(19) United States
(12) Patent Application Publication
(10) Pub. No.: US 2013/0263444 A1
(43) Pub. Date: Oct. 10, 2013

(54) CLAMPING APPARATUS FOR REMOVING CONNECTOR

(71) Applicants: CHIH-FENG LO, Tu-Cheng (TW); JUI-HSIUNG HO, Tu-Cheng (TW); CHUAN-CHI LIU, Tu-Cheng (TW)

(72) Inventors: CHIH-FENG LO, Tu-Cheng (TW); JUI-HSIUNG HO, Tu-Cheng (TW); CHUAN-CHI LIU, Tu-Cheng (TW)

(21) Appl. No.: 13/662,710

(22) Filed: Oct. 29, 2012

(30) Foreign Application Priority Data
Apr. 10, 2012 (TW) 101112686

(51) Int. Cl. H05K 13/00; B25B 27/14

(52) U.S. Cl. 29/764; 81/487

(57) ABSTRACT

A clamping apparatus includes a seat, a first guiding sleeve, a second guiding sleeve, a handle element and a clamping element. The seat includes a support portion and legs integrally formed together. The first guiding sleeve and the second guiding sleeve are mounted at opposite sides of the support portion. The handle element is slidably engaged in the first guiding sleeve and the second guiding sleeve. The clamping element is pivotally connected to one end of the handle element and is received in the second guiding sleeve in a closed position. When the handle element is slid along the seat, the first guiding sleeve and the second guiding sleeve, the clamping element moves out of the second guiding sleeve in an open position; when the handle element is released, the clamping element and the handle element automatically return to the closed position.

### BACKGROUND

1. Technical Field

The present disclosure relates to a clamping apparatus, and more particularly, to a clamping apparatus for removing a connector engaged in a socket on a printed circuit board.

2. Description of related art

Printed circuited boards (PCBs) usually include a plurality of sockets. A plurality of connectors need to be engaged with the sockets to realize electronic connection. However, the connectors are manually removed. When the connectors are tightly latched in the sockets, operators might need to apply a large force to pull the connectors. The large force might shake the sockets or the connectors. This will damage or destroy the sockets or the connectors.

Therefore, there is room for improvement within the art.

### BRIEF DESCRIPTION OF THE DRAWINGS

Many aspects of the disclosed clamping apparatus can be better understood with reference to the following drawings. The components in the drawings are not necessarily drawn to scale, the emphasis instead being placed upon clearly illustrating the principles of the present clamping apparatus.

FIG. 1 is a cross sectional view of a clamping apparatus according to an exemplary embodiment.

FIG. 2 is a state view of the clamping apparatus clamping a connector engaged in a socket on a printed circuit board.

### DETAILED DESCRIPTION

The disclosed clamping apparatus may be applied in electronic devices. In the exemplary embodiment, the clamping apparatus being used in a printed circuit board of a mobile phone is illustrated, although the disclosure is not limited thereto.

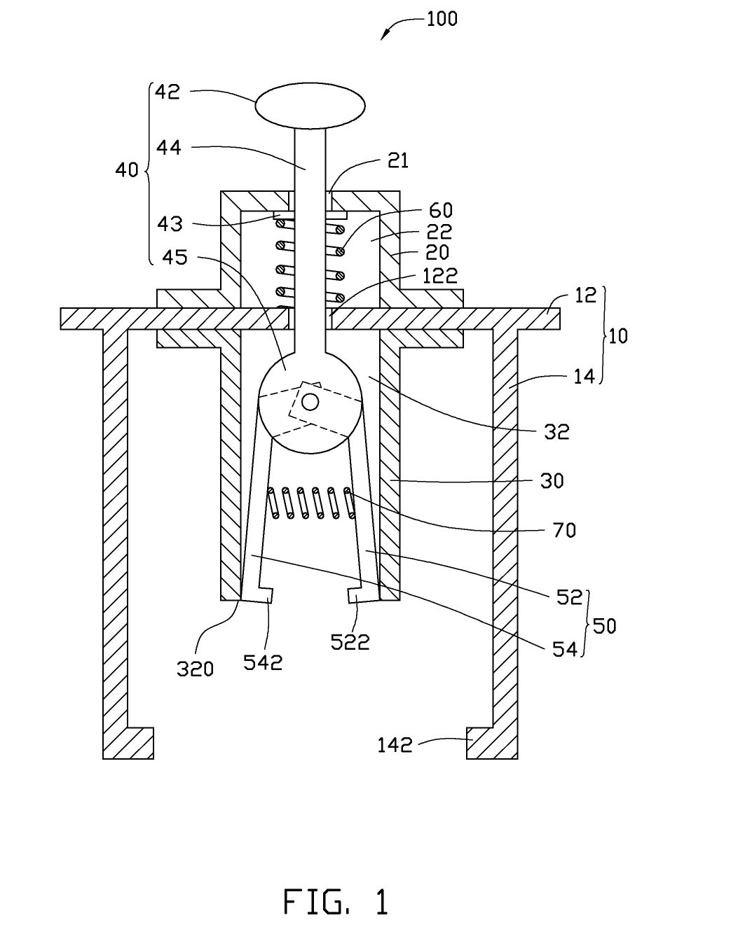

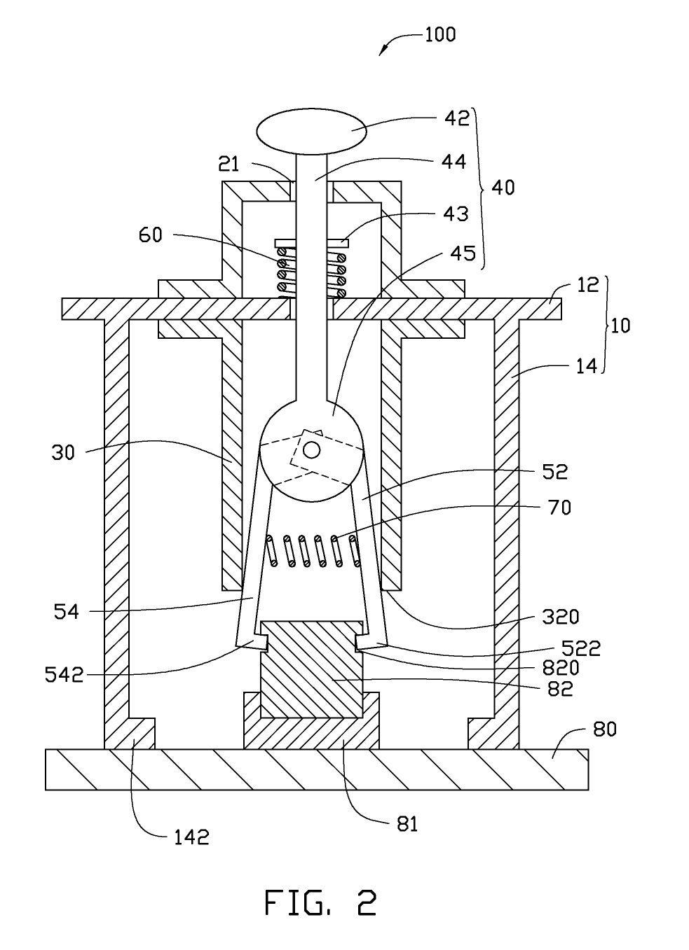

Referring to FIGS. 1 and 2, an exemplary embodiment of a clamping apparatus 100 for removing a connector 82 is shown. The connector 82 is engaged with a socket 81 on a printed circuited board 80. The connector 82 defines two latching grooves 820. The clamping apparatus 100 includes a seat 10, a first guiding sleeve 20, a second guiding sleeve 30, a handle element 40, a clamping element 50, a first elastic element 60, and a second elastic element 70.

The seat 10 includes a support portion 12 and a plurality of legs 14 integrally formed together. In this exemplary embodiment, the support portion 12 is substantially a flat plate and defines a through hole 122, for allowing the handle element 40 to extend through therefrom. Each leg 14 has a foot 142 for being positioned on the printed circuit board 80.

The first guiding sleeve 20 and the second guiding sleeve 30 are respectively mounted at opposite sides of the support portion 12 by welding or fasteners. In this exemplary embodiment, the first guiding sleeve 20 is positioned at an upper side of the support portion 12, and the second guiding sleeve 30 is positioned at a lower side of the support portion 12. The first guiding sleeve 20 defines an entrance 21 and a cylindrical first cavity 22, communicating with each other. The second guiding sleeve 30 defines a cylindrical second cavity 32 with an open end 320.

The handle element 40 includes an operating portion 42, a rod portion 44, a resisting plate 43, and a disc portion 45 integrally formed together. The operating portion 42 is held by the users. The rod portion 44 extends into the first cavity 22, from the entrance 21, and extends into the second cavity 32, through the through hole 122. The resisting plate 43 is mounted on the rod portion 44. When the handle element 40 is moved, the rod portion 44 and the resisting plate 43 can move together. The first elastic element 60 is fitted around the rod portion 44 and is positioned between the resisting plate 43 and the support portion 12. The first elastic element 60 provides a force to return the handle element 40.

The clamping element 50 is received in the second cavity 32 of the second guiding sleeve 30. The clamping element 50 includes a first arm 52 and a second arm 54 that are both pivotally connected to the disc portion 45. The first arm 52 and the second arm 54 respectively abut against the second guiding sleeve 30. The second elastic element 70 is mounted between the first arm 52 and the second arm 54. When the handle element 40 slides out from the second cavity 32, the second elastic element 70 provides an elastic force to open the clamping element 50. The first arm 52 has a first hook 522, and the second arm 54 has a second hook 542. The first hook 522 and the second hook 542 are configured for engaging with the latching grooves 820 to latch the connector 82.

In use, the user holds the clamping apparatus 100 to cause the clamping apparatus 100 to be positioned on the connector 82 on the socket 81 on the printed circuit board 80. The legs 14 support the handle element 40 and the clamping element 50. The clamping apparatus 100 is adjusted to align the clamping element 50 with the connector 82. Then, the operating portion 42 is pressed to move the rod portion 44 and the disc portion 45. The clamping element 50 is moved out of the second cavity 32 and opens under the role of the second elastic element 70, until the hooks 522, 542 are latched in the latching grooves 820. During the sliding process of the rod portion 44, the resisting plate 43 compresses the first elastic element 60. After the operating portion 42 is released, the first elastic element 60 returns the handle element 40 to an original position. Accordingly, the clamping element 50 moves the connector 82 to be separated from the socket 81. Since the first guiding sleeve 20 and the second guiding sleeve 30 guide the movement of the handle element 40 in a vertical direction, the clamping element 50 vertically moves in or out of the second cavity 32 and will not shake the connector 82 or the socket 81.

It is to be understood, however, that even through numerous characteristics and advantages of the present disclosure have been set forth in the foregoing description, together with details of assembly and function, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A clamping apparatus comprising:
a seat including a support portion and a plurality of legs integrally formed together;
a first guiding sleeve and a second guiding sleeve mounted at opposite sides of the support portion;
a handle element slidably engaged in the first guiding sleeve and the second guiding sleeve; and
a clamping element pivotally connected to one end of the handle element and received in the second guiding sleeve in a closed position;
wherein when the handle element is slid along the seat, the first guiding sleeve, and the second guiding sleeve, the clamping element moves out of the second guiding sleeve in an open position; when the handle element is released, the clamping element and the handle element automatically return to the closed position.

2. The clamping apparatus as claimed in claim 1, wherein the handle element comprises an operating portion, a rod portion, and a disc portion integrally formed together; and
the clamping element is pivotally connected to the disc portion.

3. The clamping apparatus as claimed in claim 2, wherein the first guiding sleeve defines an entrance and a cylindrical first cavity, communicating with each other; the second guiding sleeve defines a cylindrical second cavity with an open end; the support portion defines a through hole; the rod portion extends into the cylindrical first cavity from the entrance; and extends into the cylindrical second cavity through the through hole.

4. The clamping apparatus as claimed in claim 2, wherein the handle element includes a resisting plate mounted on the rod portion; a first elastic element is fitted around the rod portion and is positioned between the resisting plate and the support portion; and the first elastic element provides a force to return the handle element.

5. The clamping apparatus as claimed in claim 4, wherein the clamping element includes a first arm and a second arm; the first arm and the second arm respectively abut against the second guiding sleeve; and a second elastic element is mounted between the first arm and the second arm.

6. A clamping apparatus for removing a connector engaged in a socket on a printed circuit board, the clamping apparatus comprising:
a seat;
a guiding sleeve formed on the seat;
a handle element slidably engaged in the guiding sleeve; and
a clamping element pivotally connected to one end of the handle element and received in the guiding sleeve in a closed position;
wherein when the handle element is slid to moves the clamping element out of the guiding sleeve in an open position, the clamping element is configured for latching the connector; when the handle element is released, the handle element and the clamping element automatically return to the closed position and forcing the clamping element to remove the connector from the socket.

7. The clamping apparatus as claimed in claim 6, wherein the handle element comprises an operating portion, a rod portion, a disc portion integrally formed together; and the clamping element is pivotally connected to the disc portion.

8. The clamping apparatus as claimed in claim 7, wherein the guiding sleeve includes a first guiding sleeve and a second guiding sleeve; the first guiding sleeve defines an entrance and a cylindrical first cavity communicating with each other, the second guiding sleeve defines a cylindrical second cavity with an open end; the seat defines a through hole; and the rod portion extends into the cylindrical first cavity from the entrance, and extends into the cylindrical second cavity through the through hole.

9. The clamping apparatus as claimed in claim 8, wherein the handle element comprises a resisting plate mounted on the rod portion; a first elastic element is fitted around the rod portion, and is positioned between the resisting plate and the seat; and the first elastic element provides a force to return the handle element.

10. The clamping apparatus as claimed in claim 9, wherein the clamping element comprises a first arm and a second arm; the first arm and the second arm respectively abut against the second guiding sleeve; and a second elastic element is mounted between the first arm and the second arm.
